(19) United States
(12) Patent Application Publication
(10) Pub. No.: US 2009/0065044 A1
(43) Pub. Date: Mar. 12, 2009

(54) CONCENTRATOR-BASED PHOTOVOLTAIC SYSTEM BY PARALLIZING AND SPLITTING THE HIGH INTENSITY LIGHT

(76) Inventor: DIANA H KIM, (US)

Correspondence Address: DIANA H. KIM, 422 EVELYN AVENUE # C, ALBANY, CA, 94706, US

(21) Appl. No.: 11/852,304

(22) Filed: Sep. 9, 2007

(51) Int. Cl. H01L 31/052

(52) U.S. Cl. 136/246

(57) ABSTRACT

The present invention is a high-intensity-light split-based photovoltaic system. More particularly, it is a photovoltaic system that utilizes the sunlight according to the frequency band via splitting the concentrated high intensity light flux for the purpose of generating electricity. In the invention, the light is concentrated with the large first lens called “the concentrating lens” and then the high intensity light is parallelized with the small second lens called “the parallelizing lens” with short focal length. Finally, such parallelized high intensity light is split with a prism. As a result, the light flux is separated spatially according to its frequency so that several photovoltaic cells with different “Band Gap Energies” can be deployed to generate electricity separately at each band. The invention also employs the light recycling structure that covers the whole photovoltaic cells with mirrors to redirect the reflected light to the photovoltaic cells.

### BACKGROUND OF THE INVENTION

1. Field of the Invention

The present invention relates to a concentrator-based photovoltaic system and more particularly, to a frequency-based utilization of the sun light via splitting the high intensity light flux for the purpose of generating electricity. In the present invention, the light is concentrated by the use of large first lens and then is parallelized by the small second lens that has short focal length. Finally, the parallelized light, which is now highly intensified, is split up into different frequency bands with the use of a prism. Now, in order to convert the light energy into electricity in the most efficient way possible, disparate photovoltaic cells with distinctive “Band Gap Energy” are utilized.

2. Background of the Related Art

A photovoltaic cell is a semiconductor diode that has been carefully designed and constructed to efficiently absorb and convert solar energy into electrical energy. A simple conventional photovoltaic cell structure is depicted in FIG. 1. The figure shows the presence of sunlight on the top on the photovoltaic cell. The metallic grid of the cell creates electrical contacts of the diode and allows light to fall on the semiconductor resting in between the grid lines. This permits light to be absorbed and converted into electrical energy.

Although the photovoltaic system is extremely beneficial and useful, it presents a disadvantage: the photovoltaic system requires a large size of photovoltaic cell when to collecting light from a large area. With the photovoltaic cell being expensive and unaffordable, our only solution seems to be to conserve the use of photovoltaic cell by concentrating light energy with large concentrators of cheap costs. This would allow the use of smaller pieces of photovoltaic cells, and it would greatly reduce the cost of photovoltaic systems.

A very significant bottleneck of the today's concentrator-based photovoltaic system is the heating problem caused by the high intensity solar fluxes [Falcone-1983]. To solve such problem, there have been several methods proposed such as employing heat dispersion panel at the back of the chip [Edenburn-1984], using the heat filtering by passing through some liquid, and splitting up the light [Sabry-2002].

The first method with the heat dispersion panel has the weakness of wasting the heat energy. The second method of using the heat filter with liquid has the weakness of causing a portion of high energy components to be absorbed in the liquid and become useless. The most efficient method for the concentrator-based photovoltaic system among three methods is the one associated with light splitting. The previous work related to this area includes the use of dichroic beam splitting technique which causes light to be split into two parts: low frequency component and high frequency component [Sabry-2002]. This method causes the increment in the cost of photovoltaic cells, because of the requirement of the dichroic beam splitter. Other than the expensiveness of the use of dichroic beam splitter, the fact that splitting up photons into only two parts is not the maximum utilization of the solar energy makes the dichoric beam not a preferable choice.

The proposed invention belongs to the light splitting method. However, it uses different supplies and a slightly modified strategy than those of the existing light splitting method. This method utilizes heat energy and valid high-frequency energy very efficiently increasing the overall system performance by a significant amount.

### SUMMARY OF THE INVENTION

The proposed invention is a concentrator-based photovoltaic system which parallelizes and splits the high intensity light and substantially obviates one or more problems faced by the existing invention.

The objective of the present invention is to concentrate light and split up the highly concentrated light so that different kinds of photovoltaic cells can be employed appropriately according to the frequency bands. A very significant weakness in the existing concentrated photovoltaic system is the heating problem of the photovoltaic cell caused by the low frequency components like infrared rays. Also, the existing system presents the possibility of wasting valuable solar energy when any components of the incident light are much higher than the Band Gap Energy of a photovoltaic cell. The proposed invention is a photovoltaic system that eliminates both of the problems present in the previous invention by separating frequency components of light more spatially.

The objective and features of the present invention will be set forth in part in the following description and will become apparent to those who attempt test out this invention. They will also become evident to those who already have sufficient knowledge of solar-powered cells. The objectives of the invention may be implemented and attained by the structure pointed out in the written description and the appended drawings.

To achieve the previously mentioned objectives and other advantages, one must build a photovoltaic system in which the light is concentrated with a large first lens called the “concentrating lens”. Then the high intensity light rays enters through the second lens called “parallelizing lens”. The parallelizing lens must be arranged in such a way that the focal point of the parallelizing lens is coinciding with that of the concentrating lens.

Finally, the parallelized high intensity light undergoes fission through a prism. The light flux becomes separated spatially according to its frequency, allowing several photovoltaic cells with different “Band Gap Energy” to generate electricity separately at each band.

This present invention also employs a light recycling structure that covers the entire photovoltaic cells with mirrors to reintroduce the reflected light in the photovoltaic cells.

It is to be understood that both the preceding and following general description of the proposed invention are an explanatory intended to provide further description of the invention mentioned.

### BRIEF DESCRIPTION OF THE DRAWINGS

The accompanying drawings, which are included to provide a further understanding of the invention, illustrate embodiment(s) of the proposed invention. Combined with the description, they serve to explain the major principles of the invention. In the drawings,

FIG. 1 is a schematic of the photovoltaic cell illustrating the principle of the electricity generation;

FIG. 2 is an illustration of the overall structure of light-splitting-based photovoltaic system according to the proposed invention;

FIG. 3 is a figure illustrating the confusion of the frequency rays when the parallelizing lens is not employed;

FIG. 4 is a figure illustrating the frequency separation with the use of the parallelizing lens in the proposed invention.

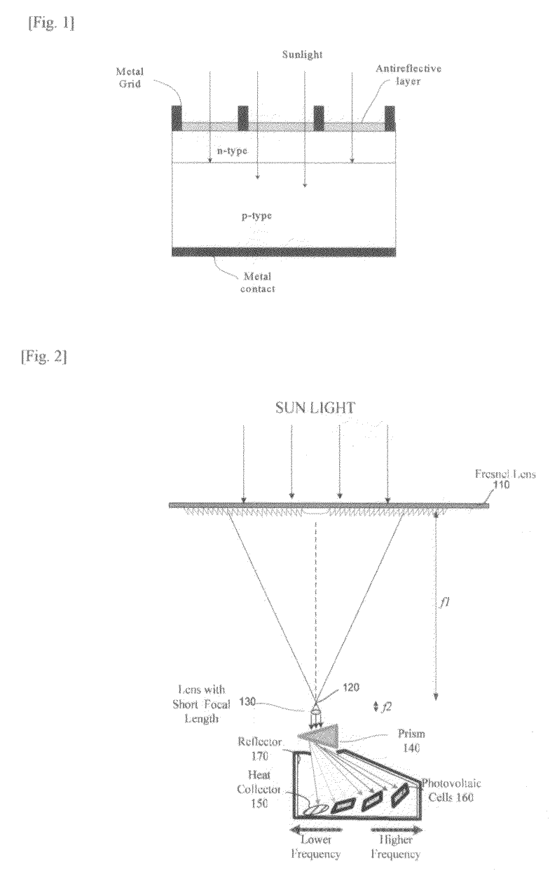

### DETAILED DESCRIPTION OF THE PREFERRED EMBODIMENT

It is known that the efficiency of photovoltaic cell decreases as the temperature increases, typically by about 0.5% per degree [Sabry-2002]. Photovoltaic cells can utilize only a fraction of the solar radiation spectrum depending on their spectral response. The part of the spectrum that lies outside the spectral response of the photovoltaic cell contributes to overheating of the device, which results in a decrease in the conversion efficiency. A better performance can be achieved by preventing this unwanted irradiation from reaching the cell, which will result in a lower temperature of the cell.

In sunlight, there exist various frequency components. The higher the photon's frequency, the bigger its energy becomes. In photovoltaic cells, the cells' Band Gap Energies vary according to the fabricated chips. and only the incident wave with high energy than Band Gap Energy contributes to generate electricity. Such features of the sunlight motivate the invention of the proposed concentrated photovoltaic system, which separates photons according to the frequency rays and generate maximum electricity.

The proposed invention is a method to efficiently separate the concentrated sunlight into different frequency components. The invention is composed of a light-concentrating lens, a light-paralleling lens, and a light-splitting prism as shown in FIG. 2.

The principle of the invention is as followed:

The large first lens, 110, is used as a light-concentrating lens that collects a large amount of sunlight. Either Fresnel lens or convex glass lens can be used as the concentrating lens. Passing through the concentrating lens 110, the sunlight becomes refracted and concentrated at the focal point 120. Then the light rays proceed onto the second lens, 130, which is located under the focal point 120 of the concentrating lens in such a way that the focal point of the second lens coincides with that of the concentrating lens.

The focal length of the second lens must be minimal enough that it could be placed at a short distance from the focal point 120. The light fluxes passing through the second lens run parallel to each other according to the optical principle of convex lens. Thus, the second lens, 130, is called “the parallelizing lens.” Since the focal length of the parallelizing lens is very short, the produced area of light flux is small. Therefore, the parallelized light fluxes are highly concentrated.

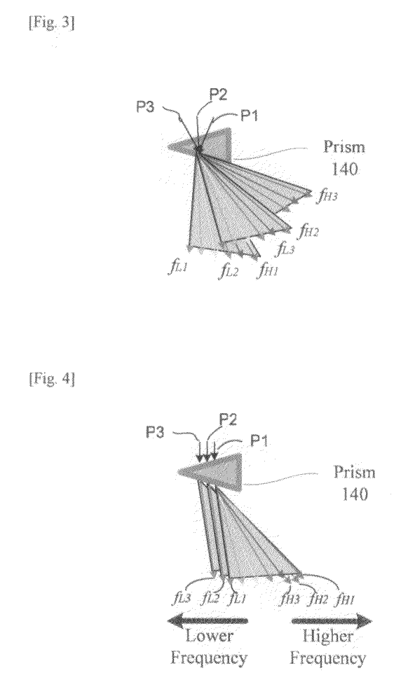

The effect of the parallelizing lens appears after the light flux passes through the prism. FIG. 3 and FIG. 4 are the detailed figures around the prism to explain the effect of the light parallelization; FIG. 3 shows the layout of light rays when the light rays are passed through the prism without becoming parallelized. FIG. 4, on the other hand, demonstrates the layout of light rays when the rays are parallelized before prism separation.

In FIG. 3, when a light beam enters the prism 140, it is refracted and split up by the prism in a way that the lower frequency components are refracted less than the higher frequency components

For a further explanation, let P1, P1 and P3 be the entering light beams and [f_{L1}, f_{H1}], [f_{L2}, f_{H2}], [f_{L3}, f_{H3}] be their frequency ranges, respectively. Without the parallelizing lens as in FIG. 3, all the incident beams, except the ones at the center, are slanted. Since the degree of refraction for each frequency component is independent on the incident angle, the refraction angles of the frequency components are rotationally shifted according to the degree of the incident angle. As a result, higher frequency components of the leftward slanted beam and the lower frequency components of the rightward slanted beam are likely to be mixed. For instance, f_{H1} of P1 and f_{L2} of P2 could be amalgamated. Thus, without the parallelized light rays, the separation of the light energy according to its frequency is not possible. This is an obvious phenomenon as shown in FIG. 3.

However, with the second lens, 130, employed in the present invention, the passing light beam is parallelized. as in FIG. 4. As can be seen in FIG. 4, the range of the split frequency of a light beam is simply a horizontally shifted version of others. For instance, the frequency range [f_{L2}, f_{H2}] of light beam P2 is only horizontal shifted from the version of the frequency range [f_{L1}, f_{H1}] of P1. As a result, lower frequency components of all light beams line up at the left side of the figure and higher frequency components line up at the right. Thus, the separation of the frequency components is achieved.

Once the light is separated into the distinctive frequency regions, the photovoltaic cell with an appropriate Band Gap Energy can be placed at each frequency region. Notice that the photovoltaic cell should be installed at a right angle to the splitting light as in FIG. 2.

With the present invention, the lower frequency components that do not generate electricity in the photovoltaic effect can be utilized for the heat-based electricity generation. Another arrangement of this invention is the encompassment of the photovoltaic cells with light reflectors such as mirrors. This way, the light components which are reflected from the surface of the photovoltaic cells are able to be redirected to the photovoltaic cells.

What is claimed is:

1. A light splitting-based photovoltaic system that is composed of a light concentrating lens at the forefront, a light parallelizing lens under the concentrating lens, and a light splitting prism underneath the light parallelizing lens. Beneath all the lenses and the prism, the system consists of photovoltaic cells with different Band Gap Energies and a mirror-based light recycling structure that covers all the photovoltaic cells.

2. A method of light-splitting with the structure of the claim 1:
concentrating the light using the foremost large lens called concentrating lens such as Fresnel lens or glass convex lens,
parallelizing the concentrated light by placing the parallelizing lens of a short focal length in the place where its the focal point coincides with that of the concentrating lens;
splitting the concentrated light into many spectral bands by placing a prism immediately after the parallelizing lens.

3. A light-splitting-based photovoltaic system according to the claim 1 that proposes the installation of the photovoltaic cells at the positions that correspond to spectral bands at a right angle with the light beam.

4. The light recycling structure of the photovoltaic system according to the claim 1, covering the whole photovoltaic cells with mirrors, except the light entering hole, to redirect the reflected light onto the photovoltaic cells.
